(19) United States
(12) Patent Application Publication
(10) Pub. No.: US 2005/0006245 A1
(43) Pub. Date: Jan. 13, 2005

(54) Multiple-step electrodeposition process for direct copper plating on barrier metals

(75) Inventors: Zhi-Wen Sun, San Jose, CA (US); Renren He, Sunnyvale, CA (US); You Wang, Cupertino, CA (US); Michael X. Yang, Palo Alto, CA (US)

Correspondence Address: PATENT COUNSEL;APPLIED MATERIALS, INC., Legal Affairs Department, P.O. Box 450A, Santa Clara, CA, 95052, US

(73) Assignee: Applied Materials, Inc.

(21) Appl. No.: 10/616,097

(22) Filed: Jul. 8, 2003

(51) Int. Cl. C25D 5/02; H01L 21/288

(52) U.S. Cl. 205/291; 205/123

(57) ABSTRACT

Embodiments of the invention teach a method for depositing a copper seed layer to a substrate surface, generally to a barrier layer. The method includes placing the substrate surface into a copper solution, wherein the copper solution includes complexed copper ions. A current or bias is applied across the substrate surface and the complexed copper ions are reduced to deposit the copper seed layer onto the barrier layer.

### BACKGROUND OF THE INVENTION

1. Field of the Invention

Embodiments of the present invention generally relate to a method to deposit a metal layer with electrochemical plating and more particularly, the metal layer is a copper seed layer.

2. Description of the Related Art

Metallization for sub-quarter micron sized features is a foundational technology for present and future generations of integrated circuit manufacturing processes. In devices such as ultra large scale integration-type devices, i.e., devices having integrated circuits with more than a million logic gates, the multilevel interconnects that lie at the heart of these devices are generally formed by filling high aspect ratio interconnect features with a conductive material (e.g., copper or aluminum). Conventionally, deposition techniques such as chemical vapor deposition (CVD) and physical vapor deposition (PVD) have been used to fill these interconnect features. However, as interconnect sizes decrease and aspect ratios increase, void-free interconnect feature fill via conventional metallization techniques becomes increasingly difficult. As a result thereof, plating techniques, such as electrochemical plating (ECP) and electroless plating have emerged as viable processes for filling sub-quarter micron sized high aspect ratio interconnect features in integrated circuit manufacturing processes.

In an ECP process sub-quarter micron sized high aspect ratio features formed into the surface of a substrate may be efficiently filled with a conductive material, such as copper. Most ECP processes are generally two stage processes, wherein a seed layer is first formed over the surface features of the substrate (this process may be performed in a separate system), and then the substrate surface features are exposed to an electrolyte solution while an electrical bias is simultaneously applied between the substrate and an anode positioned within the electrolyte solution. The electrolyte solution is generally rich in ions to be plated onto the surface of the substrate. Therefore, the application of the electrical bias drives a reductive reaction to reduce the metal ions and precipitate the respective metal. Upon precipitating, the metal plates onto the seed layer to form a film.

The process requirements for copper interconnects are becoming more stringent, as the critical dimensions for modern microelectronic devices shrink to 0.1 μm or less. As a result thereof, conventional plating processes will likely be inadequate to support the demands of future interconnect technologies. Conventional plating practices include depositing a copper seed layer via physical vapor deposition (PVD), chemical vapor deposition (CVD) or atomic layer deposition (ALD) onto a diffusion barrier layer (e.g., tantalum or tantalum nitride). However, it is extremely difficult to have adequate seed step coverage with PVD techniques, as discontinuous islands of copper agglomerates are often obtained close to the feature bottom in high aspect ratio features with PVD techniques. For CVD techniques, a thick copper layer (e.g., >200 Å) over the field is generally needed to have continuous sidewall coverage throughout the depth of the features, which often causes the throat of the feature to close before the feature sidewalls are covered. Additionally, copper purity is generally questionable in CVD processes due to difficult complete precursor-ligand removal. ALD techniques, though capable of giving generally conformal deposition with good adhesion to the barrier, take too much time to give a continuous copper film on the sidewalls. Also, alternative materials that include cobalt, nickel, ruthenium, silver and titanium nitride are gradually replacing materials used for barrier layers.

Direct electroplating on barrier materials, such as tantalum or tantalum nitride, is difficult, since these traditional barrier materials generally have insulating native oxides across the surface. Also during electroplating, conductive barrier materials (e.g., cobalt) generally will oxidize near the reductive potential of free copper ions. Therefore, the integrity of the barrier layer is compromised during the electroplating of a copper seed layer. PVD has been a preferred technique to deposit a copper seed layer. Electroless plating techniques for depositing a seed layer onto a barrier layer of tantalum or tantalum nitride are known. However, these techniques have suffered from several problems, such as adhesion failure between the copper seed layer and the barrier layer, as well as the added complexity of a complete electroless deposition system and the associated difficulties of process control. Furthermore, a well adhered seed layer has several benefits, such as protecting the barrier layer (e.g., cobalt) from the acidic solutions utilized during the electroplating of the bulk copper layer. Also, the copper seed supports the bulk copper and minimizes peeling from the barrier layer.

Therefore, there is a need for a process for depositing a copper seed layer onto a barrier layer, such as cobalt, nickel, ruthenium, silver or titanium nitride. The process should deposit the copper seed layer with a strong adhesion to the barrier layer and with good uniformity over the entire substrate surface. Also, the process should be applicable to a range of barrier materials. The barrier layers should be maintained with little or no oxidation during the seed layer deposition.

### SUMMARY OF THE INVENTION

The present invention generally provides a method for depositing a copper seed layer to a substrate surface, wherein the substrate surface includes a barrier layer. The method includes placing the substrate surface into a copper solution, wherein the copper solution includes complexed copper ions, applying a current across the substrate surface and reducing the complexed copper ions with the current to deposit the copper seed layer onto the barrier layer.

In another embodiment, the present invention provides a method for depositing a metal seed layer to a barrier layer on a substrate surface. The method includes placing the substrate surface into a solution, wherein the solution includes a metal source compound and a complexing compound, forming complexed metal ions within the solution and reducing the complexed metal ions with an electroplating technique to form the metal seed layer.

In another embodiment, the present invention provides a method for electroplating a copper seed layer to a barrier layer from a copper solution. The method includes placing a substrate surface including the barrier layer into fluid contact with the copper solution, wherein the copper solution includes copper ions and complexing compounds and reducing the copper ions with a current to form the copper seed layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a top plan view of an embodiment of an electrochemical processing system capable of implementing the method of the invention; and

FIG. 2 is a graph of a current density verses electrical potential.

### DETAILED DESCRIPTION OF THE PREFERRED EMBODIMENT

One embodiment of the invention teaches a method for depositing a copper seed layer onto a substrate surface, generally onto a barrier layer. The method includes placing the substrate surface into a copper solution which includes complexed copper ions. A current or bias is applied across the substrate surface and the complexed copper ions are reduced to deposit the copper onto the barrier layer. In one aspect, the complexed copper ions include a carboxylate ligand, such as citrate, oxalate, tartrate, EDTA and/or acetate. The barrier layer includes a metal selected from cobalt, ruthenium, nickel, tungsten, titanium and/or silver. The copper solution may also contain wetting agent or suppressor.

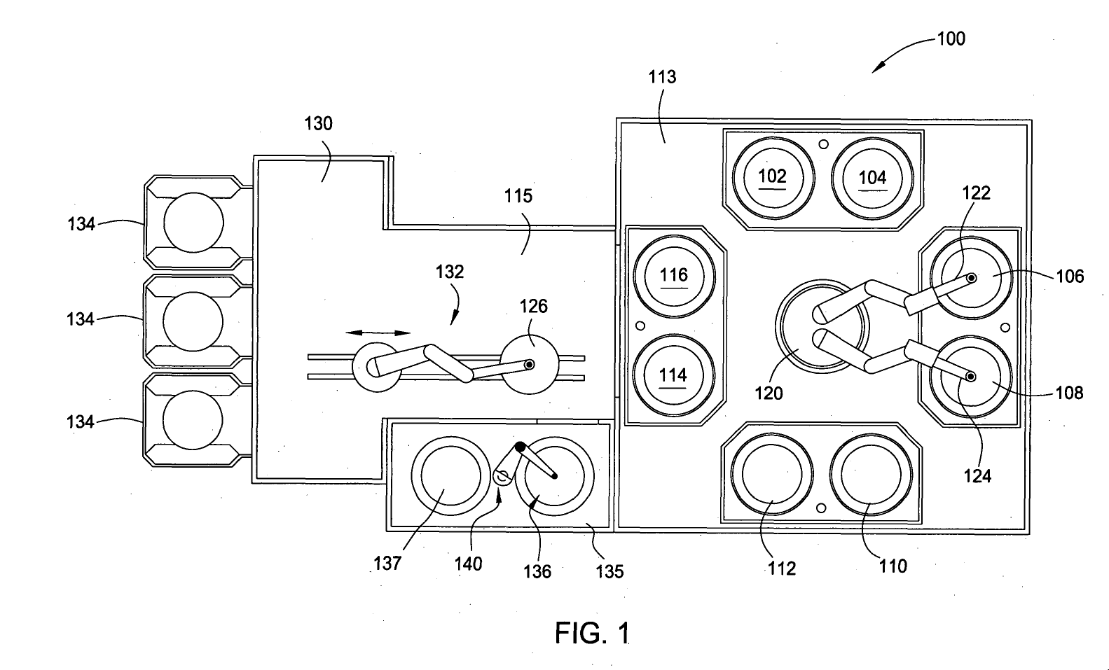

FIG. 1 is a top plan view of an embodiment of an electrochemical processing system (ECPS) 100 capable of implementing the methodology of the present invention. The ECPS 100 generally includes a processing base 113 having a robot 120 centrally positioned thereon. The robot 120 generally includes one or more robot arms 122 and 124 configured to support substrates thereon. Additionally, the robot 120 and the robot arms 122 and 124 are generally configured extend, rotate and vertically move so that the robot 120 may insert and remove substrates to and from a plurality of processing locations 102, 104, 106, 108, 110, 112, 114 and 116 positioned on the base 113. Processing locations may be configured as electroless plating cells, electrochemical plating cells, substrate rinsing and/or drying cells, substrate bevel clean cells, substrate surface clean or preclean cells and/or other processing cells that are advantageous to plating processes. Preferably, embodiments of the present invention are conducted within at least one of the processing locations 102,104, 110 and 112.

The ECPS 100 further includes a factory interface (FI) 130. The FI 130 generally includes at least one FI robot 132 positioned adjacent a side of the FI 130 that is adjacent the processing base 113. The FI robot 132 is positioned to access a substrate 126 from a substrate cassettes 134. The FI robot 132 delivers the substrate 126 to one of processing cells 114 and 116 to initiate a processing sequence. Similarly, FI robot 132 may be used to retrieve substrates from one of the processing cells 114 and 116 after a substrate processing sequence is complete. In this situation FI robot 132 may deliver the substrate 126 back to one of the cassettes 134 for removal from the system 100. Further, robot 132 also extends into a link tunnel 115 that connects factory interface 130 to processing mainframe or platform 113. Additionally, FI robot 132 is configured to access an anneal chamber 135 positioned in communication with the FI 130. The anneal chamber 135 generally includes a two position annealing chamber, wherein a cooling plate or position 136 and a heating plate or position 137 are positioned adjacently with a substrate transfer robot 140 positioned proximate thereto, e.g., between the two stations. The robot 140 is generally configured to move substrates between the respective heating 137 and cooling plates 136.

Embodiments of the invention teach the use of complexed copper sources contained within a plating solution for the ECP of copper seed layers. A plating solution containing complexed copper sources has a significantly more negative deposition potential than does a plating solution containing free copper ions. Generally, complexed copper ions have a deposition potential from about −0.9 V to about −0.3 V, while free copper ions have deposition potentials in the range from about −0.3 V to about −0.1 V, when referenced to Ag/AgCL (1M KCl), which has a potential of 0.235 V verses a standard hydrogen electrode. For example:
Cu₂(C₆H₄O₇)+2H₂O→2Cu⁰+C₆H₈O₇+O₂Δε=−0.7 V
Cu⁺²+2e⁻→Cu⁰Δε=−0.2 V.

Barrier layers, such as cobalt or nickel, have a dissolution potential in the same potential range as the deposition potential of the free copper ions. For example:
Cu⁺²+2e⁻→Cu⁰Δε=−0.2 V
Co⁰→Co⁺²+2e⁻Δε=−0.2 V.
Therefore, while free copper ions are reduced to form the copper seed layer, a cobalt or nickel barrier layer is oxidized and dissolved into the solution. Once the integrity of the barrier layer is weakened, copper can migrate through the voids of the barrier layer and contaminate other materials of the substrate.

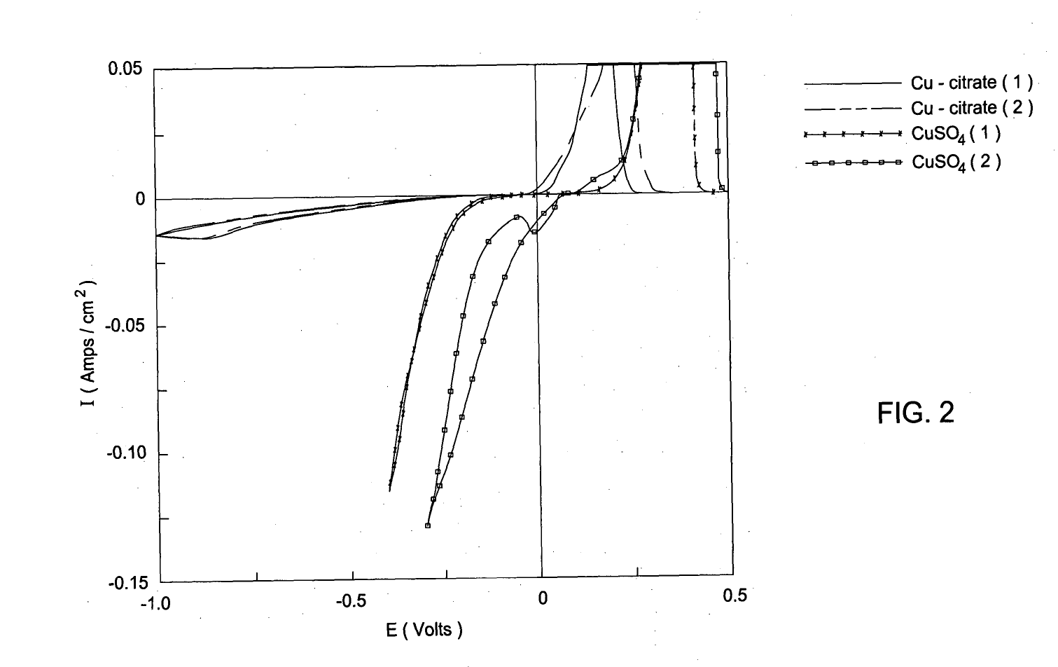

FIG. 2 is a graph representing one example of the ECP of complexed copper ions (e.g., Cu-citrate) compared to free-copper ions (e.g., CuSO₄). The graph plots current density (A/cm²) against potential (V) for a plating process. Solutions containing complexed copper ions are labeled as Cu-citrate(1) and Cu-citrate(2). The Cu-citrate(1) solution contains 0.25 M copper (II) citrate and 0.25 M sodium citrate, while the Cu-citrate(2) solution contains 0.25 M CuSO₄ and 0.5 M sodium citrate. Solutions containing free-copper ions are labeled as CuSO₄(1) and CuSO₄(2). The CuSO₄(1) solution contains 0.8 M CuSO₄ and a suppressor, while the CuSO₄(2) solution contains 0.8 M CuSO₄, a suppressor and an accelerator. The graph demonstrates that by using the complex bath, the copper deposition potential, under any practical current density of 1 mA/cm² or greater, shifted significantly to more negative values which result in no cobalt or nickel dissolution/corrosion, as the dissolution potential for these metals is outside of in the range. If less negative values of the copper deposition potential are used, barrier layer oxidation is commenced before a seed layer forms. Hence, the barrier metals are being protected during copper deposition in complex baths via a copper seed layer with potentials of more negative values.

On the other hand, the current dependence on potential for the complex bath is substantially reduced when compared to the bath with free copper ions. Therefore, the local current density variation across the substrate surface will be improved, even in the presence of a large potential gradient across the substrate surface due to the low electrical conductivity of thin barrier metals. This leads to better deposition uniformity across the substrate surface.

Suitable barrier layers to deposit metal seed layers (e.g., copper) upon include cobalt, ruthenium, nickel, tungsten, tungsten nitride, titanium, titanium nitride, and silver. Barrier layers are generally deposited by chemical vapor deposition (CVD), plasma enhanced CVD (PECVD), high density plasma CVD (HDP-CVD), atomic layer deposition (ALD), physical vapor deposition (PVD), electro- or electroless plating deposition techniques and combinations thereof.

Since the plating solution includes complexed copper ions, the deposition process initiates with a bias at a more negative potential (e.g., −0.5 V to −0.3 V) than required to deposit copper from free copper ions. Also, the bias has a more negative potential than required to oxidize the barrier layer. As the bias is applied, the complexed copper ions are chemically reduced and copper metal precipitates from the plating solution. The copper precipitate deposits or coats the barrier layer to form the copper seed layer. Once the barrier layer has a copper seed layer deposited upon, the barrier layer is protected or shielded from metal dissolution processes at less negative potentials. The deposition bias generally has a current density of about 10 mA/cm² or less, preferably about 5 mA/cm² or less, more preferably at about 3 mA/cm² or less. In one embodiment, the deposition bias has a current density in the range from about 0.5 mA/cm² to about 3.0 mA/cm².

Suitable plating solutions that may be used with the processes described herein to plate copper may include at least one copper source compound, at least one chelating or complexing compound, optional wetting agents or suppressors, optional one or more pH adjusting agents and a solvent.

Plating solutions contain at least one copper source compound complexed or chelated with at least one of a variety of ligands. Complexed copper includes a copper atom in the nucleus and surrounded by ligands, functional groups, molecules or ions with a strong finite to the copper, as opposed to free copper ions with very low finite, if any, to a ligand (e.g., water). Complexed copper sources are either chelated before being added to the plating solution (e.g., copper citrate) or are formed in situ by combining a free copper ion source (e.g., copper sulfate) with a complexing agent (e.g., citric acid or sodium citrate). The copper atom may be in any oxidation state, such as 0, 1 or 2, before, during or after complexing with a ligand. Therefore, throughout the disclosure, the use of the word copper or elemental symbol Cu includes the use of copper metal (Cu⁰), cupric (Cu⁺¹) or cuprous (Cu⁺²), unless otherwise distinguished or noted.

Examples of suitable copper source compounds include copper sulfate, copper phosphate, copper nitrate, copper citrate, copper tartrate, copper oxalate, copper EDTA, copper acetate, copper pyrophosphorate and combinations thereof, preferably copper sulfate and/or copper citrate. A particular copper source compound may have ligated varieties. For example, copper citrate may include at least one cupric atom, cuprous atom or combinations thereof and at least one citrate ligand and include Cu(C₆H₇O₇), Cu₂(C₆H₄O₇), Cu₃(C₆H₅O₇) or Cu(C₆H₇O₇)₂. In another example, copper EDTA may include at least one cupric atom, cuprous atom or combinations thereof and at least one EDTA ligand and include Cu(C₁₀H₁₅O₈N₂), Cu₂(C₁₀H₁₄O₈N₂), Cu₃(C₁₀H₁₃O₈N₂), Cu₄(C₁₀H₁₂O₈N₂), Cu(C₁₀H₁₄O₈N₂) or Cu₂(C₁₀H₁₂O₈N₂). The plating solution may include one or more copper source compounds or complexed metal compounds at a concentration in the range from about 0.02 M to about 0.8 M, preferably in the range from about 0.1 M to about 0.5 M. For example, about 0.25 M of copper sulfate may be used as a copper source compounds.

The plating solution contains one or more chelating or complexing compounds and include compounds having one or more functional groups selected from the group of carboxylate groups, hydroxyl groups, alkoxyl, oxo acids groups, mixture of hydroxyl and carboxylate groups and combinations thereof. Examples of suitable chelating compounds having one or more carboxylate groups include citric acid, tartaric acid, pyrophosphoric acid, succinic acid, oxalic acid, and combinations thereof. Other suitable acids having one or more carboxylate groups include acetic acid, adipic acid, butyric acid, capric acid, caproic acid, caprylic acid, glutaric acid, glycolic acid, formic acid, fumaric acid, lactic acid, lauric acid, malic acid, maleic acid, malonic acid, myristic acid, plamitic acid, phthalic acid, propionic acid, pyruvic acid, stearic acid, valeric acid, quinaldine acid, glycine, anthranilic acid, phenylalanine and combinations thereof. Further examples of suitable chelatinrg compounds include compounds having one or more amine and amide functional groups, such as ethylenediamine, diethylenetriamine, diethylenetriamine derivatives, hexadiamine, amino acids, ethylenediaminetetraacetic acid, methylformamide or combinations thereof. The plating solution may include one or more chelating agents at a concentration in the range from about 0.02 M to about 1.6 M, preferably in the range from about 0.2 M to about 1.0 M. For example, about 0.5 M of citric acid may be used as a chelating agent.

The one or more chelating compounds may also include salts of the chelating compounds described herein, such as lithium, sodium, potassium, cesium, calcium, magnesium, ammonium and combinations thereof. The salts of chelating compounds may completely or only partially contain the aforementioned cations (e.g., sodium) as well as acidic protons, such as Naₓ(C₆H₈₋ₓO₇) or NaₓEDTA, whereas X=1−4. Such salt combines with a copper source to produce NaCu(C₆H₅O₇). Examples of suitable inorganic or organic acid salts include ammonium and potassium salts or organic acids, such as ammonium oxalate, ammonium citrate, ammonium succinate, monobasic potassium citrate, dibasic potassium citrate, tribasic potassium citrate, potassium tartrate, ammonium tartrate, potassium succinate, potassium oxalate, and combinations thereof. The one or more chelating compounds may also include complexed salts, such as hydrates (e.g., sodium citrate dihydrate).

Although the plating solutions are particularly useful for plating copper, it is believed that the solutions also may be used for depositing other conductive materials, such as platinum, tungsten, titanium, cobalt, gold, silver, ruthenium and combinations thereof. A copper precursor is substituted by a precursor containing the aforementioned metal and at least one ligand, such as cobalt citrate, cobalt sulfate or cobalt phosphate.

Wetting agents or suppressors, such as electrically resistive additives that reduce the conductivity of the plating solution may be added to the solution in a range from about 10 ppm to about 2,000 ppm, preferably in a range from about 50 ppm to about 1,000 ppm. Suppressors include polyacrylamide, polyacrylic acid polymers, polycarboxylate copolymers, polyethers or polyesters of ethylene oxide and/or propylene oxide (EO/PO), coconut diethanolamide, oleic diethanolamide, ethanolamide derivatives or combinations thereof.

One or more pH-adjusting agents are optionally added to the plating solution to achieve a pH less than 7, preferably between about 3 and about 7, more preferably between about 4.5 and about 6.5. The amount of pH adjusting agent can vary as the concentration of the other components is varied in different formulations. Different compounds may provide different pH levels for a given concentration, for example, the composition may include between about 0.1% and about 10% by volume of a base, such as potassium hydroxide, ammonium hydroxide or combinations thereof, to provide the desired pH level. The one or more pH adjusting agents can be chosen from a class of acids including, carboxylic acids, such as acetic acid, citric acid, oxalic acid, phosphate-containing components including phosphoric acid, ammonium phosphates, potassium phosphates, inorganic acids, such as sulfuric acid, nitric acid, hydrochloric acid and combinations thereof.

The balance or remainder of the plating solution described herein is a solvent, such as a polar solvent. Water is a preferred solvent, preferably deionized water. Organic solvents, for example, alcohols or glycols, may also be used, but are generally included in an aqueous solution.

The plating solution may include one or more additive compounds. Additive compounds include electrolyte additives including, but not limited to, suppressors, enhancers, levelers, brighteners and stabilizers to improve the effectiveness of the plating solution for depositing metal, namely copper to the substrate surface. For example, certain additives may decrease the ionization rate of the metal atoms, thereby inhibiting the dissolution process, whereas other additives may provide a finished, shiny substrate surface. The additives may be present in the plating solution in concentrations up to about 15% by weight or volume, and may vary based upon the desired result after plating.

In one embodiment, a plating solution includes at least one copper source compound, at least one chelating or complexing compound and solvent. In one aspect the at least one copper source compound includes copper sulfate, the chelating compound includes citrate salt and the solvent is deionized water. Copper sulfate is dissolved in deionized water to produce a copper sulfate solution with a concentration of about 0.25 M. Similarly, sodium citrate dihydrate is dissolved in deionized water to solution with a concentration of about 0.5 M. The two aforementioned solutions are combined to form a plating solution with a pH in the range from about 5 to about 6. In another aspect, the copper source (e.g., copper sulfate) and the chelating compound (e.g., sodium citrate dihydrate) may be combined as solids and then dissolved to the acceptable concentration with water.

In another embodiment, a plating solution includes at least one copper source compound, at least one chelating or complexing compound, at least one wetting agent and solvent. In one aspect the at least one copper source compound includes copper sulfate, the chelating compound includes a citrate salt, the wetting agent includes copolymers of ethylene oxide and propylene oxide and the solvent is deionized water. The copper sulfate and the citrate solutions of above are combined with about 200 ppm of the copolymer (ethylene and propylene oxides) to form a plating solution with a pH in the range from about 5 to about 6.

In another embodiment, a plating solution includes at least one copper source compound, at least one chelating or complexing compound and solvent. In one aspect the at least one copper source compound includes copper sulfate, the chelating compound includes boric acid and the solvent is deionized water. Copper sulfate is dissolved in boric acid to form a plating solution with a pH in the range from about 5 to about 6. The copper sulfate has a concentration of about 0.25 M and the boric acid has a concentration of about 0.40 M.

In another embodiment, a plating solution includes at least one copper source compound, at least one chelating or complexing compound, at least one wetting agent and solvent. In one aspect the at least one copper source compound includes copper sulfate, the chelating compound includes a citrate salt, the wetting agent includes copolymers of ethylene oxide and propylene oxide and the solvent is deionized water. The copper sulfate and the citrate solutions of above are combined with the copolymer (ethylene and propylene oxides) to form a plating solution with a pH in the range from about 5 to about 6.

The copper seed is deposited using any of the aforementioned plating solutions within a cell on the Electra Cu ECP® system or the SlimCell Copper Plating system, both of which are available from Applied Materials, Inc. of Santa Clara, Calif. The plating cells of these systems, or other plating systems utilized, may be modified to allow a more uniform electric field than produced from the standard cell. One adjustment includes the replacement of the solid anode with a segmented anode. In another aspect, a shutter or shield is added to the cell to direct current in a more uniform field about the substrate surface.

The substrate surface, containing a barrier layer, is exposed to a plating solution. A bias commences from the anode, on the bottom of the cell, through the plating solution and across the substrate surface. The voltage is generally kept constant though the process at a range from about −0.9 V to about −0.3 V, such that the current density across the substrate surface is about 10 mA/cm² or less, preferably about 3 mA/cm² or less. The copper seed layer is deposited as the voltage or current reduces the complexed copper ions within the plating solution. The copper seed layer is deposited to a thickness in a range from about 50 Å to about 300 Å. In one aspect, the thickness is about 300 Å or less, preferably at about 200 Å or less and more preferably, at about 100 Å or less.

After the copper seed layer is deposited, the substrate is rinsed to eliminate contamination of subsequent plating solutions by the copper plating solution. The substrate is rinsed with an aqueous solution, preferably deionized water, for a period from about 5 seconds to about 30 seconds, while rotating at a rate from about 20 rpm to about 400 rpm. Subsequently, the substrate is dried via gas flow, such as nitrogen, argon, helium, hydrogen or combinations thereof.

Following the rinse/dry step, the substrate is annealed, preferably thermally annealed in an environment containing hydrogen gas, to obtain a better crystal orientation. Better crystal orientations improve electromigration resistance of the subsequent copper migration. The substrate is placed into a rapid thermal process (RTP) chamber, such as the RTP XEplus Centura® or the anneal chamber of the Electra iECP® or SlimCell plating systems, both of which are available from Applied Materials, Inc. of Santa Clara, Calif. The chamber is generally an oxygen-free environment, usually containing a gas, such as nitrogen, argon, helium, hydrogen or combinations thereof. The substrate is annealed for a period in the range from about 5 seconds to about 180 seconds at a temperature in the range from about 150° C. to about 350° C. The annealing duration may also be between about 5 seconds and about 20 seconds.

After the annealing step, a second copper deposition step, a gap-fill step, is carried out. The gap-fill step includes a solution containing about 0.05-0.5 M H₂SO₄, about 20-100 ppm level of Cl, about 8-24 ppm SPS (an accelerator), about 50-500 ppm co-polymer of ethylene oxide and propylene oxide (EO/PO co-polymer as wetting agents) and less than about 100 ppm polyamine as a leveler.

Subsequently, a second annealing step is performed, followed by a third copper deposition step, which is a bulk-fill step. The bulk-fill step includes a deposition solution that was made by adding at least one leveling agent (e.g., polyamine or polyimidazole) to the solution used during the gap-fill deposition. The leveling agent is used to achieve a better planarization. Also, pulsed, reversed current can be introduced to fine-tune the planarity of the final copper deposition.

The following non-limiting examples are provided to further illustrate embodiments of the invention. However, the examples are not intended to be all inclusive and are not intended to limit the scope of the invention described herein.

### EXAMPLES

### Example 1

A copper seed layer was deposited onto a substrate containing a barrier layer (cobalt). The copper seed was deposited using the following plating solution within a modified cell on the Electra Cu ECP® system. A substrate was disposed in a basin containing a plating solution of:
about 0.25 M copper sulfate in deionized water; and
about 0.5 M sodium citrate dihydrate in deionized water.
   Therefore, the plating solution had a pH of about 6. Electricity was applied at a current density of about 2 mA/cm². The plating process continued until the seed layer was deposited to a thickness of about 100 Å.

The substrate was rinsed in deionized water for about 30 seconds while rotating at about 100 rpm and then dried via an argon gas flow. The substrate was annealed in an O₂-free environment for 30 seconds, in the annealing chamber of the Electra iECP system.

After the annealing step, a gap-fill deposition step, is carried out. The gap-fill step includes a solution containing CuSO₄ (0.25 M), H₂SO₄ (0.3 M), 50 ppm level of Cl, 15 ppm SPS (an accelerator), 200 ppm of EO/PO co-polymer of mean molecular weight of 5,000.

Subsequently, another annealing step is performed followed by a bulk-fill deposition step. The bulk-fill step includes a deposition solution made by adding polyamine (a leveling agent) to the solution used during the gap-fill.

### Example 2

A copper seed layer was deposited onto a substrate containing a barrier layer (cobalt). The copper seed was deposited using the following plating solution within a modified cell on the Electra Cu ECP® system. A substrate was disposed in a basin containing a plating solution of:
about 0.25 M copper sulfate in deionized water;
about 0.5 M sodium citrate dihydrate in deionized water; and
about 200 ppm of polycarboxylate (EO/PO) copolymers.

The plating solution had a pH of about 5.8. Electricity was applied at a current density of about 2.0 mA/cm². The plating process continued until the seed layer was deposited to a thickness of about 100 Å.

### Example 3

A copper seed layer was deposited onto a substrate containing a barrier layer (ruthenium). The copper seed was deposited using the following plating solution within a modified cell on the Electra Cu ECP® system. A substrate was disposed in a basin containing a plating solution of:
about 0.3 M copper sulfate in deionized water; and
about 0.5 M boric acid in deionized water.

The plating solution had a pH of about 5. Electricity was applied at a current density of about 2.0 mA/cm². The plating process continued until the seed layer was deposited to a thickness of about 100 Å.

### Example 4

A copper seed layer was deposited onto a substrate containing a barrier layer (ruthenium). The copper seed was deposited using the following plating solution within a modified cell on the Electra Cu ECP® system. A substrate was disposed in a basin containing a plating solution of:
about 0.3 M copper citrate in deionized water;
about 0.5 M boric acid in deionized water; and
about 200 ppm EO/PO co-polymer.

The plating solution had a pH of about 5. Electricity was applied at a current density of about 2.0 mA/cm². The plating process continued until the seed layer was deposited to a thickness of about 100 Å.

### Example 5 (conjectural example)

A copper seed layer was deposited onto several substrates containing a cobalt barrier layer consistent to the procedure of Example 1. The substrates were examined by various means upon commencing the plating process with a seed layer thickness of about 100 Å. A tape test determined strong adhesion existed between the barrier layer and the copper seed layer. The conductivity of the copper seed layer was qualitatively high. Furthermore, little or no oxidation occurred to the barrier layer during the deposition of the seed layer.

While the foregoing is directed to embodiments of the present invention, other and further embodiments of the invention may be devised without departing from the basic scope thereof, and the scope thereof is determined by the claims that follow.

1. A method for depositing a copper seed layer onto a substrate surface, wherein the substrate surface comprises a barrier layer, comprising:
placing the substrate surface into a copper solution, wherein the copper solution comprises complexed copper ions and a pH less than 7;
applying an electrical bias to the substrate surface; and
reducing the complexed copper ions with the bias to deposit the copper seed layer onto the barrier layer.

2. The method of claim 1, wherein the barrier layer is selected from the group consisting cobalt, ruthenium, nickel, tungsten, tungsten nitride, titanium, titanium nitride and silver.

3. The method of claim 1, wherein the complexed copper ions are selected from the group consisting copper citrate, copper borate, copper tartrate, copper oxalate, copper pyrophosphate, copper acetate, copper EDTA complex and combinations thereof.

4. The method of claim 3, wherein the complexed copper ions have a concentration in a range from about 0.02 M to about 0.8 M.

5. The method of claim 4, wherein the bias is configured to generate a current density across the substrate surface that is less than about 10 mA/cm² across the substrate surface.

6. The method of claim 5, wherein the current density is in a range from about 0.5 mA/cm² to about 3 mA/cm².

7. The method of claim 6, wherein the copper seed layer has a thickness less than about 200 Å.

8. The method of claim 7, further comprising depositing a gap-fill copper layer onto the copper seed layer and wherein, depositing the gap-fill layer comprises,
placing the substrate surface into a second copper solution, wherein the second copper solution includes free-copper ions;
applying a second electrical bias to the substrate surface; and
reducing the free-copper ions with the second electrical bias to deposit the copper gap-fill layer onto the copper seed layer.

9. The method of claim 8, further comprising depositing a bulk-fill copper layer onto the copper gap-fill layer, wherein depositing the bulk-fill layer comprises,
placing the substrate surface into a third copper solution, wherein third copper solution includes the free-copper ions;
applying a third electrical bias to the substrate surface; and
reducing the free-copper ions with the third electrical bias to deposit the copper bulk-fill layer onto the copper gap-fill layer.

10. The method of claim 9, wherein at least one leveling agent is added to the second copper solution to form the third copper solution.

11. A method for depositing a metal seed layer onto a barrier layer on a substrate surface, comprising:
placing the substrate surface into a solution, wherein the solution is acidic and comprises a metal source compound and a complexing compound;
forming complexed metal ions within the solution; and
reducing the complexed metal ions with an electroplating technique to form the metal seed layer.

12. The method of claim 11, wherein the metal seed layer comprise copper.

13. The method of claim 12, wherein the barrier layer is selected from the group consisting cobalt, ruthenium, nickel, tungsten, tungsten nitride, titanium, titanium nitride and silver.

14. The method of claim 12, wherein the complexed metal ions are selected from the group consisting metal citrates, metal borates, metal tartrates, metal oxalates, metal pyrophosphates, metal acetates, metal EDTA complexes and combinations thereof.

15. The method of claim 14, wherein the metal source compound has a metal concentration in a range from about 0.02 M to about 0.8 M.

16. The method of claim 15, wherein the complexing compound has a concentration in a range from about 0.02 M to about 1.6 M.

17. The method of claim 14, wherein the electroplating technique comprises a bias configured to generate a current density that is less than about 10 mA/cm² across the substrate surface.

18. The method of claim 17, wherein the current density is in a range from about 0.5 mA/cm² to about 3 mA/cm².

19. The method of claim 18, wherein the metal seed layer has a thickness less than about 200 Å.

20. The method of claim 19, further comprising depositing a gap-fill copper layer onto the metal seed layer and wherein, depositing the gap-fill layer comprises,
placing the substrate surface into a copper solution, wherein the copper solution includes free-copper ions;
applying a second electrical bias to the substrate surface; and
reducing the free-copper ions with the second electrical bias to deposit the copper gap-fill layer onto the metal seed layer.

21. The method of claim 20, wherein depositing the bulk-fill copper layer onto the copper gap-fill layer comprises,
placing the substrate surface into a second copper solution, wherein second copper solution includes the free-copper ions;
applying a third electrical bias across the substrate surface; and
reducing the free-copper ions with the third electrical bias deposit the copper bulk-fill layer onto the copper gap-fill layer.

22. The method of claim 21, wherein at least one leveling agent is added to the copper solution to form the second copper solution.

23. A method for electroplating a copper seed layer to a barrier layer from a copper solution, comprising:
placing a substrate surface comprising the barrier layer into fluid contact with the copper solution, wherein the copper solution comprises copper ions and complexing compounds; and
reducing the copper ions with an electrical bias to form the copper seed layer.

24. The method of claim 23, wherein the barrier layer is selected from the group consisting cobalt, ruthenium, nickel, tungsten, tungsten nitride, titanium, titanium nitride and silver.

25. The method of claim 23, wherein the copper solution comprises at least one copper source compound selected from the group consisting copper citrate, copper borate, copper tartrate, copper oxalate, copper pyrophosphate, copper acetate, copper EDTA complex and combinations thereof.

26. The method of claim 24, wherein the electrical bias is configured to generate a current density less than about 10 mA/cm² across the substrate surface.

27. The method of claim 26, wherein the current density is in a range from about 0.5 mA/cm² to about 3 mA/cm².

28. The method of claim 14, wherein the copper ions have a metal concentration in a range from about 0.02 M to about 0.8 M.

29. The method of claim 15, wherein the complexing compounds have a concentration in a range from about 0.02 M to about 1.6 M.

30. The method of claim 27, wherein the copper seed layer has a thickness less than about 200 Å.

31. The method of claim 30, further comprising depositing a gap-fill copper layer onto the copper seed layer and wherein, depositing the gap-fill layer comprises,
placing the substrate surface into a second copper solution, wherein the second copper solution includes free-copper ions;
applying a second bias across the substrate surface; and
reducing the free-copper ions with the second bias to deposit the copper gap-fill layer onto the copper seed layer.

32. The method of claim 31, wherein depositing a bulk-fill copper layer onto the copper gap-fill layer comprises,
placing the substrate surface into a third copper solution, wherein third copper solution includes the free-copper ions;
applying a third bias across the substrate surface; and
reducing the free-copper ions with the third bias deposit the copper bulk-fill layer onto the copper gap-fill layer.

33. The method of claim 32, wherein at least one leveling agent is added to the second copper solution to form the third copper solution.
